(19) United States
(12) Patent Application Publication
(10) Pub. No.: US 2026/0358412 A1
(43) Pub. Date: Nov. 12, 2026

(54) SEMICONDUCTOR TEST DEVICE CAPABLE OF TESTING HIGHSPEED INTERFACE

(71) Applicants: TECHWIDU CO., LTD., Suwon-si Gyeonggi-do (KR); IDT INC., Hwaseong-si Gyeonggi-do (KR)

(72) Inventors: Hyoung-Rae KIM, Hwaseong-si Gyeonggi-do (KR); Young-Geun PARK, Hwaseong-si Gyeonggi-do (KR)

(21) Appl. No.: 19/442,971

(22) Filed: Jan. 7, 2026

Related U.S. Application Data
(63) Continuation of application No. PCT/KR2025/009075, filed on Jun. 27, 2025.

(30) Foreign Application Priority Data
May 7, 2025 (KR) 10-2025-0059261

(51) Int. Cl. G01R 31/317; G06F 11/26; H02H 7/00; H10P 72/00

(52) U.S. Cl. CPC G01R 31/31713; G06F 11/261; H02H 7/008; H10P 72/06

(57) ABSTRACT

A semiconductor test device includes a contact portion having a plurality of needles allowed to be in contact with devices under test (DUTs), a test module including a test IC and a PMIC, and interfaced with the contact portion through pogo pins, a test controller provided in the test module and configured to test the DUT in conjunction with the test IC and the PMIC, and a test server configured to receive test results of the DUTs from the test controller. The test IC and the PMIC test signal integrity and power integrity of the DUTs according to a signal received from the test controller.

### BACKGROUND OF THE INVENTION

### Field of the Invention

The present invention relates to a semiconductor test device capable of testing a high-speed interface, and more particularly to a semiconductor test device capable of testing a high-speed interface while ensuring power and signal integrity.

### Description of the Related Art

Quality assessment during semiconductor production is achieved through integrated circuit (IC) testing. All ICs need to be tested according to specifications to ensure quality.

Automated Test Equipment (ATE) is used to provide power supply and stimulation to a device under test (DUT) and measure a signal compared to an expected value.

In this regard, FIG. 1 illustrates a configuration of a semiconductor test device related to the present invention. Referring to FIG. 1, the semiconductor test device may include a tester 101, a power supply unit 120, a tester head 130, and a test module 200. The test module 200 may include a connector 202, a DUT array, a chuck 240, and a probe card 260.

In terms of structure, the semiconductor test device supplies signals (such as test patterns) and power from the tester (or ATE) to the tester head 130 via a wire connected thereto. The semiconductor test device receives test results of each DUT through the wire and compares and reviews the test results at the tester.

Therefore, the semiconductor test device of FIG. 1 may experience power integrity (PI) and signal integrity (SI) issues, making it difficult to ensure power and signal integrity. Meanwhile, high-speed testing may be difficult, and resources of high-cost tester equipment may inevitably be limited. In addition, when the DUT is upgraded or replaced with a next generation DUT, the tester (or ATE) needs to be replaced accordingly, which leads to additional problems.

In this regard, it is essential that signals be input from the tester equipment through cables and that a configuration include components that implement an operation of branching (multiplexing) a plurality of test signals. Furthermore, the tester equipment itself inevitably needs to be implemented in a complex structure, and the manufacturing cost is high.

### SUMMARY OF THE INVENTION

The present invention provides a semiconductor test device that ensures integrity of power and signals and enables testing of high-speed interfaces.

The present invention is intended to address an issue in which the tester needs to be replaced to match the upgraded or next generation DUT.

The present invention is intended to address an issue in which a component for implementing an operation of branching (multiplexing) a plurality of test signals must be provided.

The present invention is intended to address an issue in which the tester equipment itself inevitably needs to be implemented in a complex structure and the manufacturing cost is high.

In accordance with the present invention, the above and other objects can be accomplished by the provision of a semiconductor test device capable of testing a high-speed interface, the semiconductor test device including a contact portion having a plurality of needles allowed to be in contact with devices under test (DUTs), a test module including a test IC and a PMIC, and interfaced with the contact portion through pogo pins, a test controller provided in the test module and configured to test the DUT in conjunction with the test IC and the PMIC, and a test server configured to receive test results of the DUTs from the test controller. The test IC and the PMIC test signal integrity and power integrity of the DUTs according to a signal received from the test controller.

According to an embodiment, the test controller may include an interface operably coupled to the PMIC, the test IC, an external memory, and the test server, and a CPU operably coupled to the interface, and configured to control the test IC and the PMIC according to pattern signals for performing tests based on test items and wafer or package tray map information.

According to an embodiment, the test controller may further include a memory operably coupled to the CPU and configured to store result values for the test items, and an AI engine operably coupled to the CPU and configured to learn information about the result values for the test items, optimize a test time of the DUT, and evaluate a test item of a specific DUT.

According to an embodiment, the test server may be configured to determine priorities of the test items based on training data related to information about result values of the test items, and determine whether defects originate from semiconductor design or from semiconductor processing based on defect information according to a plurality of wafers or packaged products.

According to an embodiment, the AI engine may be configured to learn design information stored in the test server and determine improvement points in circuits, layouts, or mask manufacture based on defect frequency occurring in actual test items, infer contamination levels of equipment according to a process flow stored in the test server, and process flow information including an input time through the equipment, and derive an optimal semiconductor process including equipment maintenance and replacement to minimize semiconductor process defects based on the contamination levels of the equipment and the inferred process flow information.

According to an embodiment, the test IC may include an interface operably coupled to the DUT and the PMIC, a phase locked loop (PLL) configured to receive a reference clock from a clock signal oscillator (TXCO) and generate multiple frequencies by compensating for a phase difference between an input signal and an output signal, a timing generator operably coupled to the PLL and configured to control timing of a clock and a digital signal to be applied to the DUT and generate a test pattern signal, and a data converter circuit configured to convert the digital signal to an analog signal or the analog signal to the digital signal.

According to an embodiment, the test IC may be configured to generate signals related to a clock, a data rate, and data delay in the interface of the DUT to allow the test controller to simultaneously or individually control test items of the DUT, and determine whether the test of the DUT has passed or failed based on input and output data information and the test items in conjunction with the test controller and transmit a determination result to the test controller.

According to an embodiment, the test controller may be configured to control the test IC so that the test IC performs a function of a virtual GPU when the DUT is a high bandwidth memory (HBM), control the test IC to test a function to read and write test pattern data of the HBM and a function to control an interface speed, control the test IC to test a function of controlling skew of input and output pins, and determine whether the HBM has passed or filed the test according to test items of the HBM in conjunction with the test IC.

According to an embodiment, the PMIC may include a power shutoff part configured to stop operation or block power to the DUT so that the PMIC and the DUT are protected from damage, a dynamic voltage scaling part configured to dynamically vary a voltage applied to the DUT according to a load of the DUT, a DC-DC converter configured to perform conversion of voltage and power applied to the dynamic voltage scaling part, a current limiter configured to perform control so that a current decreases when the DUT is shorted or the current greater than or equal to a threshold is detected, and a current sensing part configured to sense a current of the DUT.

According to an embodiment, the current sensing part may be configured to sense a first current of the DUT through a first current path having a first impedance and a fourth impedance, and sense a second current of the DUT through a second current path having a second impedance and a third impedance, which are greater than the first impedance, the first current path may be a path in which a first contact point and a second contact point of the DUT are connected through a voltage regulator via the first impedance and the fourth impedance, the second current path may be a path in which the first contact point and the second contact point of the DUT are connected through a voltage sensing part via the second impedance and the third impedance, and the voltage sensing part may transfer a feedback signal to the voltage regulator.

According to an embodiment, the semiconductor test device may further include a switch configured to perform control so that a first path between the DUT and the test IC and a second path between the DUT and the PMIC are opened or connected. The test controller may be configured to cause the test IC and the PMIC to perform a self-diagnostic test when the first path and the second path are turned off. The test controller may be configured to cause the DUT to be in a contact state, the first path to be an on state, and the second path to be in an off state, and perform control so that the test IC tests the DUT.

According to an embodiment, the test controller may be configured to cause the DUT to be in a contact state, the first path to be in an off state, and the second path to be in an on state, and perform control so that the PMIC performs a current test on input and output pins of the DUT during open and shorted states, and cause the DUT to be in an open state, the first path to be an on state, and the second path to be in an on state, and allow the PMIC to perform loop-back testing on the test IC.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates a configuration of a semiconductor test device related to the present invention;

FIG. 2 illustrates a configuration of the semiconductor test device capable of testing a high-speed interface according to the present invention;

FIG. 3 illustrates a cross-sectional view of a test module including a probe card shown in FIG. 2;

FIG. 4 illustrates an example structure including the probe card and a DUT shown in FIG. 2;

FIG. 5 illustrates a detailed configuration of a test controller operating in conjunction with a test IC and a PMIC according to the present invention;

FIG. 6 illustrates a detailed configuration of a test IC operating in conjunction with the DUT and the PMIC according to the present invention;

FIG. 7 illustrates a detailed configuration of the PMIC operating in conjunction with the DUT and the test IC according to the present invention;

FIG. 8 illustrates a configuration and operation for 4-wire sensing for power distribution according to the present invention;

FIG. 9 illustrates a test configuration in which the test IC and the PMIC are coupled to the DUT through switches according to the present invention; and

FIGS. 10A and 10B illustrate configurations in which the PMIC performs an open-short test of the DUT according to the present invention.

### DETAILED DESCRIPTION OF THE INVENTION

A semiconductor test device capable of testing a high-speed interface according to the present invention includes a contact portion having a plurality of needles allowed to be in contact with devices under test (DUTs), a test module including a test IC and a PMIC, and interfaced with the contact portion through pogo pins, a test controller provided in the test module and configured to test the DUT in conjunction with the test IC and the PMIC, and a test server configured to receive test results of the DUTs from the test controller, wherein the test IC and the PMIC test signal integrity and power integrity of the DUTs according to a signal received from the test controller.

Hereinafter, preferred embodiments of the present invention will be described in detail with reference to the attached drawings. Prior thereto, terms or words used in this specification and claims should not be construed as limited to usual or dictionary meanings, and should be interpreted as having meanings and concepts consistent with the technical idea of the present invention based on the principle that an inventor may appropriately define a concept of a term to describe the invention of the inventor in the best way possible. Therefore, the embodiments described in this specification and the configurations shown in the drawings are only one of the most preferred embodiments of the present invention and do not represent the entire technical idea of the present invention. Thus, it should be understood that, at the time of filing this application, there may be various equivalents and modifications that can replace the embodiments and configurations.

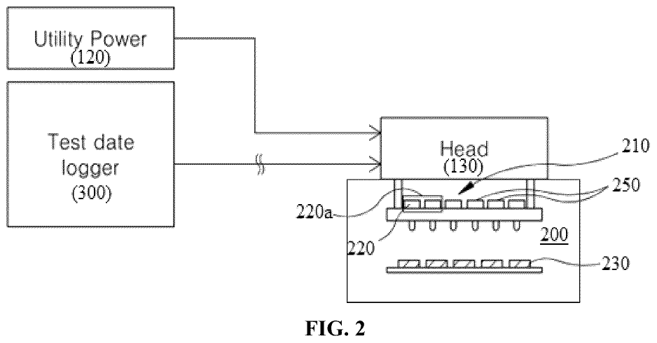

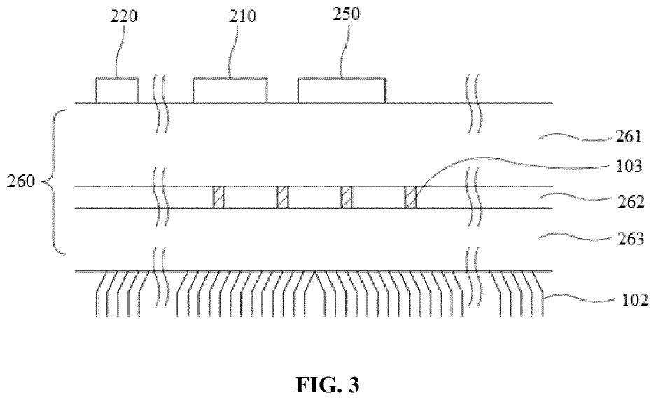

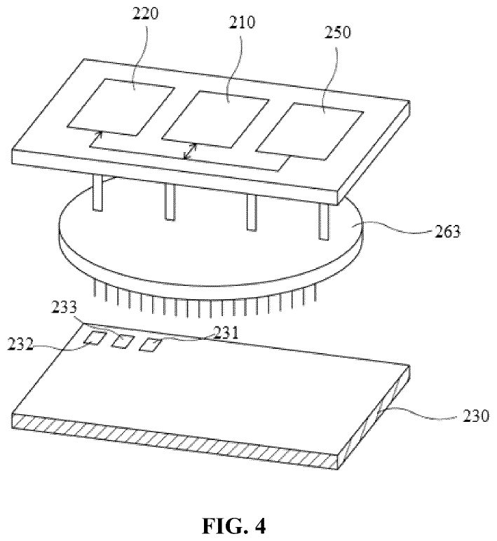

Hereinafter, the semiconductor test device capable of testing the high-speed interface according to the present invention is described. In this regard, FIG. 2 illustrates a configuration of the semiconductor test device capable of testing the high-speed interface according to the present invention. FIG. 3 illustrates a cross-sectional view of a test module including a probe card shown in FIG. 2. Meanwhile, FIG. 4 illustrates an example structure including the probe card and a DUT of FIG. 2.

Referring to FIGS. 2 to 4, the semiconductor test device may include a contact portion 102, a test module 200, a test controller 250, and a test server 300.

The contact portion 102 may include a plurality of needles that may be in contact with DUTs 230. The test module 200 may include a test IC 210 and a PMIC 220. The PMIC 220 may be formed inside an interface IC 220a. The test module 200 may be configured to interface with the contact portion 102 through pogo pins 103.

The test controller 250 may be provided in the test module 200. The test controller 250 may be configured to test the DUTs 230 in conjunction with the test IC 210 and the PMIC 220. The test server 300 may be configured to receive test results of the DUTs 230 from the test controller 250 through a communication module. The test IC 210 and the PMIC 220 may test signal integrity and power integrity of the DUTs 230 according to signals received from the test controller 250.

In this regard, the DUT 230 may include an I/O pad 231 serving as an input/output terminal for testing signal integrity, a power pad 232 serving as a power terminal for testing power integrity, and a ground pad 233.

Meanwhile, the semiconductor test device does not include a separate tester, and the test IC 210 formed on the probe card 260 directly operates in conjunction with a memory such as an HBM or an SoC. Accordingly, the semiconductor test device is characterized in that high-speed testing may be enabled by optimizing SI characteristics and PI characteristics.

According to the semiconductor test device of the present invention, there is no need for a separate test data logger. Existing test equipment companies have been improving performance of conventional testers through structural optimization. However, the present invention changes this paradigm by directly testing the DUT using the test IC 210 and the dedicated PMIC 220 in accordance with a signal received from the test controller 250, without test equipment. Therefore, a test result of the DUT may be transmitted to a PC or the test server 300 through a separate communication module, enabling the test result to be compared and reviewed on the PC or other terminal devices.

Therefore, according to the present invention, it is possible to i) minimize issues of power integrity (PI) and signal integrity (SI), ii) allow high-speed testing of a large number of DUTs, and iii) minimize equipment and devices required for a test system. In addition, according to the present invention, iv) even when the DUT performance is upgraded or replaced with a next-generation higher standard, it is only necessary to upgrade and apply the test IC 210, the PMIC 220, and the test controller 250 in the existing test system. Therefore, there is an effect of minimizing consumption of resources for replacing the equipment. Meanwhile, the DUT of the present invention may be applied not only to i) a CPU, ii) a GPU, iii) an HBM memory, iv) an AI processor, v) an AP or modem, or various SoCs, but also to various types of semiconductor components without limitation.

Meanwhile, the probe card 260 of the present invention may be implemented as shown in FIG. 3, and the probe card 260 of the present invention may be similar in structure to a conventional probe card. That is, an interposer 262 and a ceramic substrate 263 may be disposed below a PCB substrate 261. The PCB substrate 261 and the ceramic substrate 263 may be electrically connected through a plurality of pogo pins 103, and a plurality of needles or a medium capable of exchanging electrical characteristics in contact or non-contact with the DUT pad depending on the needs of the invention may be formed as the contact portion 102 at a lower side of the ceramic substrate 263.

In other words, the probe card 260 of the present invention may be implemented in a form in which the ceramic substrate 263 is disposed below the interposer 262 and the ceramic substrate 263 has MEMS probe needles. In addition, various forms may be implemented as long as electrical contact between the interposer 262 and the ceramic substrate 263 is possible as necessary.

FIG. 4 is a schematic diagram illustrating a relationship between the actual DUT and the probe card 260. In this regard, the test controller 250 may be configured as a separate board as necessary. It is desirable to minimize paths between the DUT and the PMIC 220, and between the DUT and the test IC 210, from the viewpoint of SI and PI. In the present invention, at least one of i) the test controller 250, ii) the test IC 210, and iii) the PMIC 220 is arranged on the PCB substrate 261. Each element will be described in detail below.

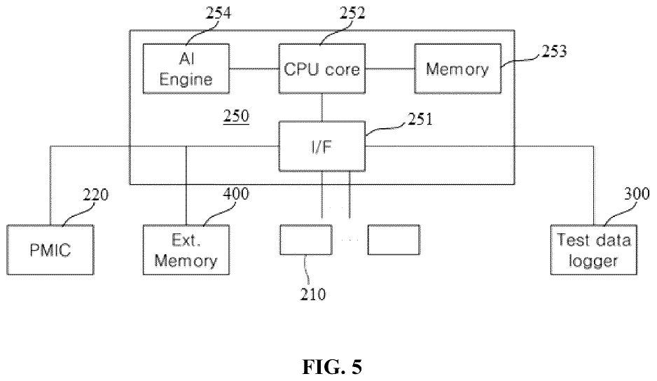

In this regard, FIG. 5 illustrates a detailed configuration of the test controller that operates in conjunction with the test IC and the PMIC according to the present invention. Referring to FIGS. 2 to 5, the test controller 250 may include an interface 251 and a CPU 252. The test controller 250 may further include a memory 253 and an AI engine 254.

The interface 251 may be operably coupled to the test IC 210, the PMIC 220, the test server 300, and an external memory 400. The CPU 252 may be operably coupled to the interface 251. The CPU 252 may be configured to control the test IC 210 and the PMIC 220 according to pattern signals for performing tests based on test items and wafer or package tray map information.

The memory 253 may be operably coupled to the CPU 252 and configured to store result values for test items. The AI engine 254 may be operably coupled to the CPU 252. The AI engine 254 may be trained using information of result values for test items to optimize a DUT test time. The AI engine 254 may be configured to be trained using information about result values for test items and evaluate test items of a specific DUT.

The test controller 250 of the present invention may perform tests based on map information of a test PGM of the test server 300 (or test data logger). The tests may be performed according to the test vectors, test items, and map information of a wafer or a package tray based on the map information of the test PGM. The package tray may be a device fixed by a socket or a ring. Various pattern signals and test items may be used to control each of the test IC 210 and the PMIC 220 in order to perform tests based on the map information of the test PGM. The test controller 250 may be implemented as an FPGA, an MCU, a CPU, an ASIC, or an independent module configured using these devices.

Meanwhile, the test server 300 (or test data logger) performs functions of storing and analyzing results of tests performed by the test controller 250, and a general server may be applied or the server may be replaced by a PC, etc.

A function of the AI engine 254 in the test controller 250 is to sequentially perform tests on the items to be tested on the PC or the server. The test controller 250 transmits the test results back to the PC or the test server 300. The test controller 250 determines test information transmitted from the test IC 210 and the PMIC 220 with regard to each test item. The test controller 250 is provided to perform training using information about result values of each test item to optimize a DUT test time or to evaluate test items of specific DUTs more intensively.

For example, even when the DUT is less likely to fail in a specific item of correlation results among several items, if failure occurs, the AI engine 254 may repeat the test. Therefore, in this case, by repeating the test, the AI engine 254 may improve yield by reducing overkill or misjudgment. Conversely, based on evaluation information of a specific item, the AI engine 254 may easily determine whether the DUT is defective, thereby significantly reducing the test time.

Upon receiving final results, the test server 300 determines priorities of test items based on AI training data. The test server 300 may determine whether a defect originates from design or from a process based on defect information corresponding to the same process unit (Lot) of a plurality of wafers or packaged products. Therefore, according to determination results in the test server 300, information for improving products may be provided to each department through a test engineer.

Design information stored in the test server 300 may be learned by AI to find improvement points of design (circuit, layout, or mask fabrication) according to defect frequency occurring in actual test items. In addition, by inferring process flow information (equipment, equipment contamination level, an actually input time, etc. according to each process flow) in the test server 300, it is possible to infer a method of finding an optimal process recipe using an AI algorithm.

For example, when a defect occurs in which an operation distribution of a certain circuit exceeds a trimming range or a trimming interval is excessively wide, causing accuracy problems, corresponding design improvement points may be identified. In addition, when defects frequently occur in an outer ring pattern of a wafer, it may be determined that a problem occurred during photoresist spin. Therefore, recommendations such as equipment maintenance, equipment replacement, or process recipe modification may be provided.

In summary, the test server 300 may determine priorities of test items based on training data related to information about result values of the test items. The test server 300 may determine whether defects originate from semiconductor design or from semiconductor processing based on defect information according to the same process unit of a plurality of wafers or packaged products.

In this regard, the AI engine 254 learns design information stored in the test server 300 and determines improvement points in circuits, layouts, or mask manufacture based on defect frequency occurring in actual test items. The AI engine 254 may infer contamination levels of equipment according to a process flow stored in the test server 300, and process flow information including an input time through the equipment. Based on the contamination levels of the equipment and the inferred process flow information, the AI engine 254 may derive an optimal semiconductor process including equipment maintenance and replacement to minimize semiconductor process defects.

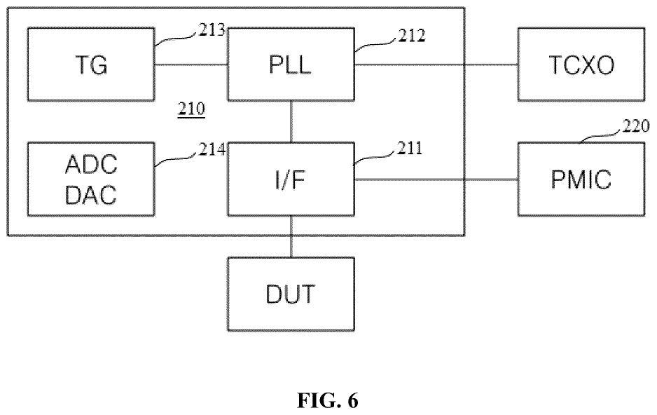

Hereinafter, a detailed configuration and operation of the test IC 210 of the present invention will be described. In this regard, FIG. 6 illustrates the detailed configuration of the test IC operating in conjunction with the DUT and the PMIC according to the present invention. Referring to FIGS. 2 to 6, the test IC 210 may include an interface 211, a phase locked loop (PLL) 212, a timing generator 213, and a data converter (ADC/DAC) circuit 214. The PLL 212 and the timing generator 213 may be implemented as a PLL circuit and a timing generation circuit.

The interface 211 may be operably couple to the DUT and the PMIC 220. The PLL 212 may be configured to receive a reference clock from a clock signal oscillator (TXC O) and generate multiple frequencies by compensating for a phase difference between an input signal and an output signal. The timing generator 213 may be operably coupled to the PLL 212. The timing generator 213 may be configured to control timing of a clock and a digital signal to be applied to the DUT and generate a test pattern signal. The data converter circuit 214 may be configured to convert the digital signal to an analog signal or the analog signal to the digital signal.

In the present invention, the test IC 210 refers to a dedicated IC formed to perform roles and functions of an IC corresponding to an actual operating environment of the DUT according to each DUT type such as a CPU, an AP, a GPO, a high bandwidth memory (HBM), other memory, or SoC, which are measured elements. For example, for testing of the HBM, the HBM, in which a DRAM is stacked on a logic IC for interface with a GPU, requires an I/F of the logic IC and a virtual GPU.

It is necessary to have a built-in function to read and write data of various test patterns in the memory by performing a virtual GPU function. In addition, it is necessary to have a built-in function to control an interface speed and a function to control a time skew of the I/O pins. The test IC 210 operates in conjunction with the test controller 250 to determine whether the input/output data information and the test vector, which is a test item, are non-defective/defective, and transmits this information to the test controller 250.

The timing generator 213 may precisely generate timing for the clock and digital signals to be applied to the DUT. For example, the timing generator 213 may set pulse width, delay, and period of the clock and the digital signals. The timing generator 213 may perform generation and synchronization functions of various test pattern signals.

The PLL 212 may receive a stable reference clock from an external TXCO and generate a high-speed clock. The TXCO may be implemented as a temperature compensated crystal oscillator. The PLL 212 compensates for a phase difference between an input signal and an output signal and generates multiple frequencies. The TXCO minimizes frequency variation due to temperature changes to provide a stable clock signal and provides a reference clock for the PLL 212 and the timing generator 213. The data converter circuit 214 may include an ADC and a DAC used in a high-speed interface.

The test IC 210 receives the same power as the input/output power of the DUT from the PMIC 220, and use the power for an input/output operation, which similarly varies. The test IC 210 generates signals related to clock, data rate, and delay such as skew for the DUT I/O, so that the test controller 250 may perform control simultaneously or individually.

In summary, the test IC 210 may generate signals related to clock, data rate, and data delay for the DUT interface, enabling the test controller 250 to simultaneously control or individually control the test items of the DUT. The test IC 210 may determine whether the test of the DUT has passed or failed based on the input and output data information and the test items in conjunction with the test controller 250. The test IC 210 may transmit information indicating whether the test of the DUT has passed or failed based on the input and output data information and test items.

Meanwhile, when the DUT is an HBM, the test controller 250 may control the test IC 210 so that the test IC 210 performs a function of the virtual GPU. The test controller 250 may control the test IC 210 to test a function to read and write test pattern data of the HBM and a function to control the interface speed. The test controller 250 may control the test IC 210 to test a function of controlling skew of the I/O pins. The test controller 250, in conjunction with the test IC 210, may determine whether the HBM has passed or filed the test according to test items of the HBM.

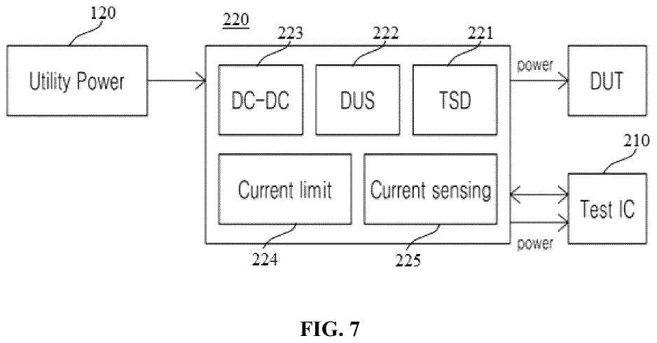

Hereinafter, a detailed configuration and operation of the PMIC 220 of the present invention will be described. In this regard, FIG. 7 illustrates a detailed configuration of the PMIC operating in conjunction with the DUT and the test IC according to the present invention. Referring to FIGS. 2 to 7, the PMIC 220 may include a power shutoff part 221, a dynamic voltage scaling part 222, a DC-DC converter (for example, Buck, Buck-boost, Boost, or LDO) 223, a current limiter 224, and a current sensing part 225.

The power shutoff part 221 may be configured to stop operation or block power to the DUT so that the PMIC 220 and the DUT are protected from damage. The power shutoff part 221 may be implemented as a TSD (Thermal Shutdown) device. The dynamic voltage scaling part 222, the DC-DC converter 223, the current limiter 224, and the current sensing part 225 may be implemented as a dynamic voltage scaling circuit, a DC-DC conversion circuit, a current limiting circuit, and a current sensing circuit, respectively.

The dynamic voltage scaling part 222 may be configured to dynamically vary the voltage applied to the DUT according to a load of the DUT. The DC-DC converter 223 may be configured to perform conversion of voltage and power applied to the dynamic voltage scaling part 222. When a short circuit occurs in the DUT or when a current greater than or equal to a threshold is detected, the current limiter 224 may perform control to reduce or cut off the current.

The PMIC 220 may supply the voltage to the test IC 210 and the DUT corresponding to the test IC 210. Based on the information received from the test controller 250, voltage control and the amount of current are monitored, so that the test IC 210 may evaluate data of unclear characteristics such as shmoo data. The DC-DC converter 223 and an LDO (Low Dropout Regulator) have high-precision multi-level output and may perform various functions such as current monitoring and 4-wire sensing. The high-precision multi-level output may be associated with reducing power loss through voltage conversion, power conversion, and stable supply.

The TSD of the power shutoff part 221 performs a function of automatically stopping operation or blocking power when high heat is generated, thereby preventing damage to the PMIC 220 and the DUT. The DVS (Dynamic Voltage Scaling) of the dynamic voltage scaling part 222 performs a function of dynamically varying the voltage according to the working load in order to optimize power efficiency. The current limiter 224 performs a function of protecting the DUT and the PMIC 220 by limiting current when the DUT is shorted due to failure or when excessive current is consumed compared to a normal IC. The current sensing part 225 may perform current monitoring inside the circuit by incorporating an ADC, and may monitor the power consumption of the DUT.

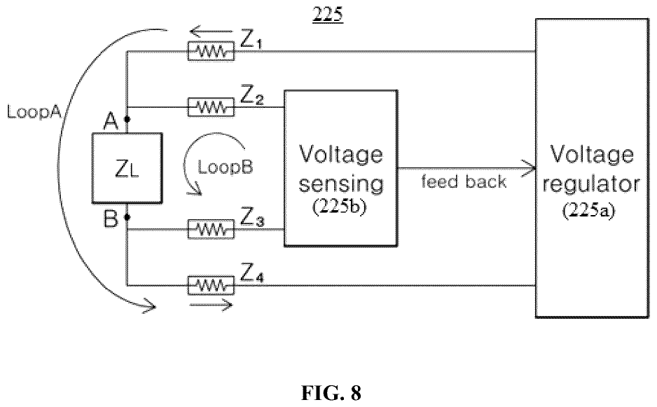

Meanwhile, FIG. 8 illustrates a configuration and operation for 4-wire sensing for power distribution according to the present invention. In this regard, unlike the present invention, a conventional test system does not receive power under the control of the PMIC, but directly receives power from an external tester or an independent power supply. Therefore, an impedance value corresponding to Loop A of FIG. 8 becomes relatively large, so that power integrity cannot be ensured.

The PMIC 220 of the present invention uses a sensing scheme in which a current supply line and a voltage measurement line are separated to reduce measurement errors due to 4-wire sensing (Kelvin sensing using voltage drop). The PMIC 220 of the present invention has a feedback path so that a voltage actually applied to the DUT is input as a target voltage considering PI characteristics. Factors influencing PI characteristics may include impedance expressed as R, L, and C resulting from contact between the needles and pads, and impedance generated along the path from the PMIC 220 to the needles.

Referring to FIG. 8, nodes A and B represent contact points of the pads of the actual DUT. Further, Z₁ and Z₄ of Loop A schematically represent the impedance (R, L, C) along the power and GND supply paths from the PMIC, which are desirably maintained at minimum values considering IR drop and voltage ringing. The impedances of Z₂ and Z₃ in the Loop B, which is a sensing path, may be higher than the impedances of Z₁ and Z₄. That is, loop A is a heavy-current and low-impedance path, and Loop B is a current path that carries a significantly small current compared to Loop A, so the magnitude of its impedance has little influence.

Referring to FIGS. 2 to 8, the current sensing part 225 may sense a first current of the DUT through a first current path having a first impedance Z₁ and a fourth impedance Z₄. The current sensing part 225 may sense a second current of the DUT through a second current path having a second impedance Z₂ and a third impedance Z₃, which are greater than the first impedance Z₁. The first current path is a path in which a first contact point and a second contact point of the DUT are connected through a voltage regulator 225a via the first impedance Z₁ and the fourth impedance Z₄. The second current path is a path in which the first contact point and the second contact point of the DUT are connected through a voltage sensing part 225b via the second impedance Z₂ and the third impedance Z₃. The voltage sensing part 225b may transfer a feedback signal to the voltage regulator 225a.

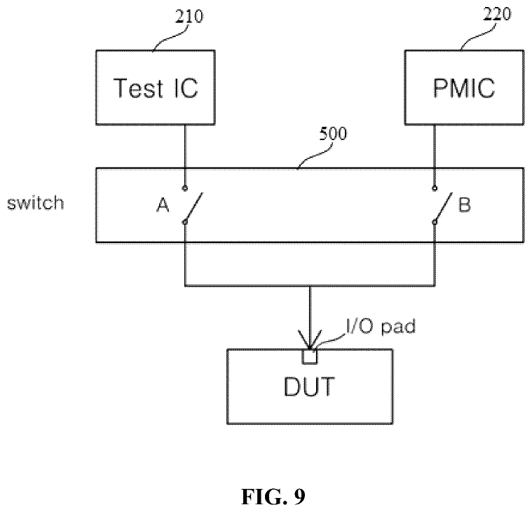

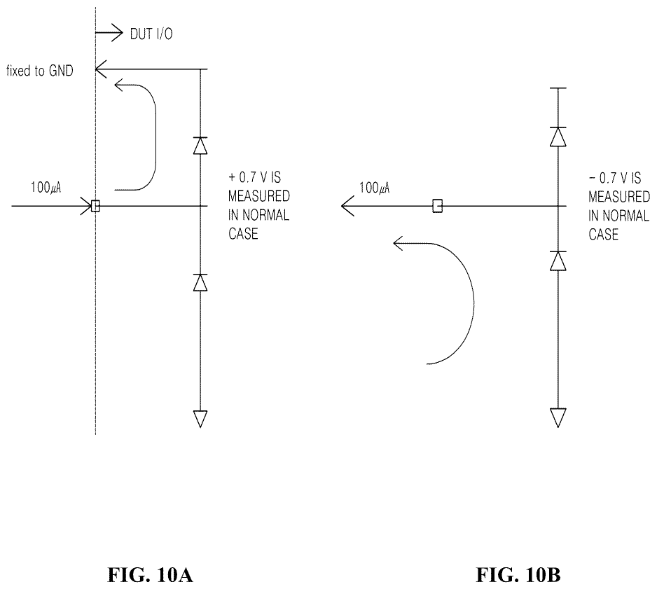

Hereinafter, a correlation between the test IC 210 and the PMIC 220 will be described. In this regard, FIG. 9 illustrates a test configuration in which the test IC and the PMIC are coupled to the DUT through switches according to the present invention. Meanwhile, FIGS. 10A and 10B illustrate configurations in which the PMIC performs an open-short test on the DUT according to the present invention.

Referring to FIGS. 9, 10A and 10B, during an open-short test, VDD power is forcibly set to GND and current is forced to measure a voltage of a pull-up diode, which is different from a general PMIC. The PMIC 220 is required to accurately measure a diode voltage by an ADC according to sourcing or sinking by setting a specific current.

The PMIC 220 has a built-in current sourcing and sinking function to perform open/short testing for each I/O pin of the DUT, thereby determining whether contact is properly established. In this regard, a relay device capable of passing a voltage of approximately −1 V to +1 V regardless of the polarity of the voltage may be used for a switch 500. A magnetic device, a photo-MOS device, or a MEMS device may be used as the relay device. In particular, for operation in a state where a first path, which is terminal A of the switch 500, is on, a MEMS SPDT (Single Pole Double Throw) switch having a high bandwidth may be used. The PMIC 220 may apply a specified current, for example, approximately ±100 μA, in an on-state of a second path, which is terminal B of the switch 500, through open/short testing to measure a voltage of a pull-up/pull-down diode of the DUT.

Meanwhile, Table 1 shows diagnostic content of the testing performed depending on the states of terminal A and terminal B of the switch. Referring to Table 1, various tests may be performed depending on the states of terminal A and terminal B of the switch. In addition, not only DUT testing but also a self-diagnostic function may be performed.

TABLE 1

| DUT | Terminal A | Terminal B | |
|---|---|---|---|
| contact | of switch | of switch | Diagnostic content |
| Don't | off | off | Test IC and PMIC each perform |
| care | | | self-diagnostic test. |
| on | on | off | Test IC performs DUT H/S testing. |
| on | off | on | PMIC performs open/short testing. |
| off | on | on | PMIC performs SMT and loopback |
| | | | testing of test IC, and open/short |
| | | | testing of test IC itself. |

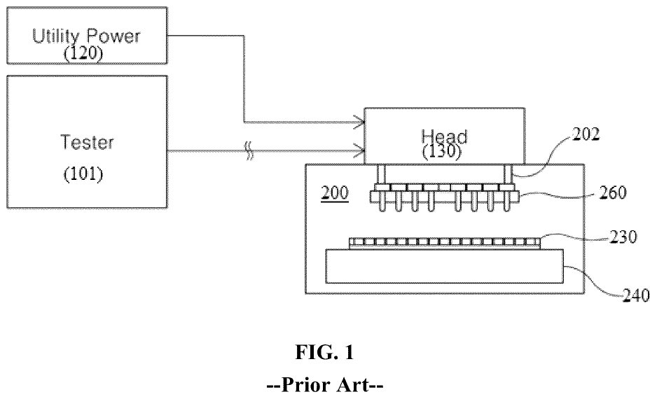

Referring to FIGS. 1 to 10B and Table 1, the semiconductor test device may further include the switch 500 that performs control so that the first path between the DUT and the test IC 210 and the second path between the DUT and the PMIC 220 are opened or connected. The test controller 250 may cause the test IC 210 and the PMIC 220 to perform a self-diagnostic test when the first path and the second path are turned off. The test controller 250 may cause the DUT to be in a contact state, the first path to be an on state, and the second path to be in an off state, and may perform control so that the test IC 210 tests the DUT.

The test controller 250 may cause the DUT to be in a contact state, the first path to be in an off state, and the second path to be in an on state, and may perform control so that the PMIC performs a current test on input and output pins of the DUT during open and shorted states. The test controller 250 may cause the DUT to be in an open state, the first path to be an on state, and the second path to be in an on state, and may allow the PMIC 220 to perform loop-back testing on the test IC 210.

The foregoing describes the semiconductor test device capable of testing a high-speed interface according to the present invention. The technical effects of the semiconductor test device capable of testing the high-speed interface according to the present invention may be summarized as follows, without being limited thereto.

According to the present invention, power integrity and signal integrity may be ensured in the semiconductor test device capable of testing a high-speed interface.

According to the present invention, when the DUT is upgraded or replaced with a next generation DUT, the tester (or ATE) does not need to be replaced to match therewith, but the test IC and the dedicated PMIC may upgrade only the test controller.

According to the present invention, even without components used to implement a multiplexing operation on a plurality of test signals, the test IC and the dedicated PMIC may directly test the DUT according to signals received from the test controller.

According to the present invention, without complicating the tester equipment itself or increasing manufacturing cost, the test results of the DUT may be transmitted to a PC or a test server through a communication module, and the test results may be compared and reviewed on the PC or other terminals.

The technical effects of the semiconductor test device capable of testing a high-speed interface according to the present invention may be summarized as follows, but are not limited thereto.

According to the present invention, power integrity and signal integrity may be ensured in the semiconductor test device capable of testing a high-speed interface.

According to the present invention, when the DUT is upgraded or replaced with a next generation DUT, the tester (or ATE) does not need to be replaced to match therewith, but the test IC and the dedicated PMIC may upgrade only the test controller.

According to the present invention, even without components used to implement a multiplexing operation on a plurality of test signals, the test IC and the dedicated PMIC may directly test the DUT according to signals received from the test controller.

According to the present invention, without complicating the tester equipment itself or increasing manufacturing cost, the test results of the DUT may be transmitted to a PC or a test server through a communication module, and the test results may be compared and reviewed on the PC or other terminals.

Even though the present invention has been described above in relation to specific embodiments of the present invention, this is only an example and the present invention is not limited thereto. A person of ordinary skill in the technical field to which the present invention pertains may change or modify the described embodiments without departing from the scope of the present invention, and various modifications and variations are possible within the scope of equivalence of the technical idea of the present invention and the scope of the patent claims described below.

1. A semiconductor test device capable of testing a high-speed interface, the semiconductor test device comprising:
a contact portion having a plurality of needles allowed to be in contact with devices under test (DUTs);
a test module including a test IC and a PMIC, and interfaced with the contact portion through pogo pins;
a test controller provided in the test module and configured to test the DUT in conjunction with the test IC and the PMIC; and
a test server configured to receive test results of the DUTs from the test controller,
wherein the test IC and the PMIC test signal integrity and power integrity of the DUTs according to a signal received from the test controller.

2. The semiconductor test device according to claim 1, wherein the test controller comprises:
an interface operably coupled to the PMIC, the test IC, an external memory, and the test server; and
a CPU operably coupled to the interface, and configured to control the test IC and the PMIC according to pattern signals for performing tests based on test items and wafer or package tray map information.

3. The semiconductor test device according to claim 2, wherein the test controller further comprises:
a memory operably coupled to the CPU and configured to store result values for the test items; and
an AI engine operably coupled to the CPU and configured to learn information about the result values for the test items, optimize a test time of the DUT, and evaluate a test item of a specific DUT.

4. The semiconductor test device according to claim 3, wherein the test server is configured to:
determine priorities of the test items based on training data related to information about result values of the test items, and
determine whether defects originate from semiconductor design or from semiconductor processing based on defect information according to a plurality of wafers or packaged products.

5. The semiconductor test device according to claim 4, wherein the AI engine is configured to:
learn design information stored in the test server and determine improvement points in circuits, layouts, or mask manufacture based on defect frequency occurring in actual test items,
infer contamination levels of equipment according to a process flow stored in the test server, and process flow information including an input time through the equipment, and
derive an optimal semiconductor process including equipment maintenance and replacement to minimize semiconductor process defects based on the contamination levels of the equipment and the inferred process flow information.

6. The semiconductor test device according to claim 2, wherein the test IC comprises:
an interface operably coupled to the DUT and the PMIC;
a phase locked loop (PLL) configured to receive a reference clock from a clock signal oscillator (TXCO) and generate multiple frequencies by compensating for a phase difference between an input signal and an output signal;
a timing generator operably coupled to the PLL and configured to control timing of a clock and a digital signal to be applied to the DUT and generate a test pattern signal; and
a data converter circuit configured to convert the digital signal to an analog signal or the analog signal to the digital signal.

7. The semiconductor test device according to claim 6, wherein the test IC is configured to:
generate signals related to a clock, a data rate, and data delay in the interface of the DUT to allow the test controller to simultaneously or individually control test items of the DUT, and
determine whether the test of the DUT has passed or failed based on input and output data information and the test items in conjunction with the test controller and transmit a determination result to the test controller.

8. The semiconductor test device according to claim 6, wherein the test controller is configured to:
control the test IC so that the test IC performs a function of a virtual GPU when the DUT is a high bandwidth memory (HBM),
control the test IC to test a function to read and write test pattern data of the HBM and a function to control an interface speed,
control the test IC to test a function of controlling skew of input and output pins, and
determine whether the HBM has passed or filed the test according to test items of the HBM in conjunction with the test IC.

9. The semiconductor test device according to claim 6, wherein the PMIC comprises:
a power shutoff part configured to stop operation or block power to the DUT so that the PMIC and the DUT are protected from damage;
a dynamic voltage scaling part configured to dynamically vary a voltage applied to the DUT according to a load of the DUT;
a DC-DC converter configured to perform conversion of voltage and power applied to the dynamic voltage scaling part;
a current limiter configured to perform control so that a current decreases when the DUT is shorted or the current greater than or equal to a threshold is detected; and
a current sensing part configured to sense a current of the DUT.

10. The semiconductor test device according to claim 9, wherein:
the current sensing part is configured to:
sense a first current of the DUT through a first current path having a first impedance and a fourth impedance, and
sense a second current of the DUT through a second current path having a second impedance and a third impedance, which are greater than the first impedance,
the first current path is a path in which a first contact point and a second contact point of the DUT are connected through a voltage regulator via the first impedance and the fourth impedance,
the second current path is a path in which the first contact point and the second contact point of the DUT are connected through a voltage sensing part via the second impedance and the third impedance, and
the voltage sensing part transfers a feedback signal to the voltage regulator.

11. The semiconductor test device according to claim 6, further comprising a switch configured to perform control so that a first path between the DUT and the test IC and a second path between the DUT and the PMIC are opened or connected,
wherein the test controller is configured to:
cause the test IC and the PMIC to perform a self-diagnostic test when the first path and the second path are turned off, and
cause the DUT to be in a contact state, the first path to be an on state, and the second path to be in an off state, and perform control so that the test IC tests the DUT.

12. The semiconductor test device according to claim 11, wherein the test controller is configured to:
cause the DUT to be in a contact state, the first path to be in an off state, and the second path to be in an on state, and perform control so that the PMIC performs a current test on input and output pins of the DUT during open and shorted states, and
cause the DUT to be in an open state, the first path to be an on state, and the second path to be in an on state, and allow the PMIC to perform loop-back testing on the test IC.
